(19) United States
(12) Patent Application Publication
(10) Pub. No.: US 2018/0097156 A1
(43) Pub. Date: Apr. 5, 2018

(54) Optoelectronic Lighting Device and Method for the Production of an Optoelectronic Lighting Device

(71) Applicant: OSRAM Opto Semiconductors GmbH, Regensburg (DE)

(72) Inventors: Christian Leirer, Regensburg (DE); Alexander Linkov, Regensburg (DE); Matthias Sperl, Mintraching (DE); Matthias Kiessling, Bad Abbach (DE)

(73) Assignee: OSRAM Opto Semiconductors GmbH, Regensburg (DE)

(21) Appl. No.: 15/560,140

(22) PCT Filed: Mar. 18, 2016
(86) PCT No.: PCT/EP2016/055926

§ 371 Date: Sep. 20, 2017

(30) Foreign Application Priority Data
Mar. 20, 2015 (DE) 10 2015 104 220.7

(51) Int. Cl. H01L 33/58; H01L 33/50; H01L 33/00

(52) U.S. Cl. CPC H01L 33/58; H01L 33/005; H01L 33/507

(57) ABSTRACT

An optoelectronic lighting device and a method for manufacturing an optoelectronic lighting device are disclosed. In an embodiment the device includes a carrier and a light-emitting diode arranged on the carrier having a light-emitting surface. The device further includes a microlens structure including a plurality of microlenses, wherein the microlens structure is arranged on the light-emitting surface of the diode and a conversion layer arranged on the microlens structure, wherein the light-emitting surface is configured to emit light, wherein the microlens structure images, at least in part, the light, and wherein the conversion layer converts the light.

This patent application is a national phase filing under section 371 of PCT/EP2016/055926, filed Mar. 18, 2016, which claims the priority of German patent application 10 2015 104 220.7, filed Mar. 20, 2015, each of which is incorporated herein by reference in its entirety.

### TECHNICAL FIELD

The invention relates to an optoelectronic lighting device and a method for manufacturing an optoelectronic lighting device.

### BACKGROUND

In the case of thin conversion layers that are applied by means of spray coating, the large differences in the optical wavelengths within the conversion layer (silicone/converter mixture) lead, for some applications, to an unacceptable color-over-angle behavior (color homogeneity) in the case of white-converted, blue chips. Perpendicular, blue emission from the chip undergoes little conversion on account of the low thickness, but a very pronounced conversion occurs at large angles.

Similarly, this behaviour applies to conversion platelets (silicone/converter mixture) which are produced in a separate method by means of screen printing and are subsequently placed onto the blue chip by machine.

Previously, diffuser material (e.g., Al₂O₃) was added to the silicone/converter mixture, or deposited on the conversion layer as a separate layer, for the purposes of improving the color homogeneity. On account of the increased scattering connected therewith, the color homogeneity can be improved to a certain extent.

However, on account of the increased scattering, light is in part also scattered back in the direction of the substrate or chip, and said light may be partly absorbed in the process (depending on the reflectivity of the surface, excitation in the p-n junction). This may lead to loss of effectivity.

### SUMMARY OF THE INVENTION

Embodiments provide an efficient concept which improves a color homogeneity of light from a light-emitting diode that has been converted by a conversion layer.

According to one aspect, provision is made of an optoelectronic lighting device, comprising: a carrier, on which a light-emitting diode is arranged, wherein a microlens structure that comprises a plurality of microlenses is arranged on a light-emitting surface of the diode, wherein a conversion layer is arranged on the microlens structure, such that light emitted by the light-emitting surface can be imaged, at least in part, by the microlens structure and then converted.

According to a further aspect, provision is made of a method for producing an optoelectronic lighting device, comprising the following steps: providing a carrier, on which a light-emitting diode is arranged, arranging a microlens structure that comprises a plurality of microlenses on a light-emitting surface of the light-emitting diode, arranging a conversion layer on the microlens structure such that the light emitted by the light-emitting surface can be imaged, at least in part, by the microlens structure and then converted.

Thus, embodiments of the invention comprise, in particular and inter alia, the concept of initially arranging a microlens structure that comprises a plurality of microlenses in relation to the emission direction of the light-emitting surface of the light-emitting diode and only then providing the conversion layer. In particular, this brings about the technical advantage that the light that is emitted by means of the light-emitting structure is initially imaged by the microlens structure and only then converted by means of the conversion layer. In particular, this brings about improved mixing of the different conversion paths, which, in turn, ultimately brings about an improvement in the color-over-angle behavior. In particular, the better mixing emerges from the additional light scattering on account of the microlens structure. A color homogeneity can be improved, in particular by a predetermined minimum distance or a predetermined minimum spacing between the microlens structure and the conversion layer. This holds true, in particular, if the microlens structure should comprise one or more spherical lenses, which is described in more detail below.

A microlens within the meaning of the present invention has, in particular, a dimension which is of the order of a few micrometers, in particular of a few 10 μm, in particular of a few 100 μm. Preferably, a microlens has a diameter of between 5 μm and 100 μm.

A conversion layer within the meaning of the present invention is configured, in particular, to convert, at least in part, the light which is emitted by means of the light-emitting surface of the light-emitting diode into light which has a wavelength or a wavelength range that differs from the wavelength or the wavelength range of the light which is emitted by means of the light-emitting surface. By way of example, the light which is emitted by the light-emitting surface can be referred to as primary light. By way of example, the converted light can be referred to as secondary light. According to an embodiment, the conversion layer comprises a phosphor.

A microlens structure within the meaning of the present invention comprises, e.g., a matrix made of microlenses. Such a matrix made of microlenses comprises, e.g., a plurality of columns and, e.g., a plurality of lines, each comprising microlenses.

A light-emitting diode may also be abbreviated as LED.

According to an embodiment, provision is made of a plurality of light-emitting diodes. Explanations that are made in the context of a light-emitting diode apply analogously to a plurality of light-emitting diodes.

According to an embodiment, provision is made for the microlens structure to comprise a substrate that comprises a plurality of microlenses, said substrate being arranged on the light-emitting surface. That is to say that, in particular, the substrate comprising the plurality of microlenses is a component which is formed separately from the light-emitting diode. Hence, a microlens structure can be produced separately from the light-emitting diode. This has, in particular, the advantage of an efficient and simplified production of the optoelectronic lighting device. Hence, provision may be made according to one embodiment for a substrate that comprises a plurality of microlenses to be produced or provided, said substrate subsequently being arranged on the light-emitting surface.

According to an embodiment, provision is made for the microlens structure to be formed as a substrate that comprises a plurality of microlenses. That is to say that, in particular, the microlens structure consists of a substrate which comprises a plurality of microlenses.

According to an embodiment, provision is made for the plurality of microlenses of the substrate to be formed integrally with the latter. That is to say that, in particular, the plurality of microlenses and the substrate form a common component. In particular, this brings about the technical advantage that an efficient and simplified production of the substrate that comprises the plurality of microlenses is facilitated. In particular, the substrate and the plurality of microlenses may, for example, advantageously be produced in a common production step.

In another embodiment, provision is made for the plurality of microlenses of the substrate to be formed separately from the latter. That is to say that, in particular, the plurality of microlenses of the substrate and the substrate form separate components. Hence, it is possible to initially provide a substrate, on which the plurality of microlenses are subsequently arranged, with this substrate with the plurality of microlenses subsequently being arranged on the light-emitting surface. In particular, this brings about the technical advantage that the substrate and the microlenses can be produced independently of one another, which, for example, may facilitate great flexibility in the production process.

According to another embodiment, provision is made for at least some of the plurality of microlenses of the microlens structure to be formed as singulated microlenses such that the microlenses that are formed in a singulated manner are arranged separately from one another on the light-emitting surface. In particular, this brings about the technical advantage that said at least some microlenses can be produced separately from the light-emitting diode which, for example, may bring about great flexibility in the production process. By way of example, provision is made according to an embodiment for all microlenses of the microlens structure to be formed as singulated microlenses such that the microlenses that are formed in a singulated manner are arranged separately from one another on the light-emitting surface. Thus, singulated microlenses are elements or components that are formed separately from one another.

According to an embodiment, provision is made for the microlenses that are formed in a singulated manner to be each formed as a sphere. In particular, this brings about the technical advantage that the microlenses are easy to produce from a technical point of view. According to an embodiment, provision is made for the sphere to be a glass sphere. That is to say that, in particular, the microlenses that are formed in a singulated manner are glass spheres. A plastic sphere may be provided in place of a glass sphere according to an embodiment. That is to say that, in particular, the microlenses that are formed in a singulated manner are plastic spheres according to an embodiment.

In accordance with a further embodiment, provision is made for the microlens structure to be adhesively bonded onto the light-emitting surface. In particular, this brings about the technical advantage that efficient fastening of the microlens structure onto the light-emitting surface is facilitated.

According to an embodiment, the microlens structure is adhesively bonded onto the light-emitting surface by means of an adhesive on the light-emitting surface. Such an adhesive comprises silicone in particular. That is to say that, for example, use is made of a silicone adhesive in order to adhesively bond the microlens structure onto the light-emitting surface.

According to an embodiment, provision is made for the adhesive bonding of the microlens structure onto the light-emitting surface to comprise curing of the adhesive, in particular of the silicone.

According to an embodiment, the silicone is a clear silicone. In particular, this brings about the technical advantage that a light yield of the light-emitting diode can be improved.

According to an embodiment, provision is made for the adhesive, in particular the silicone to be diluted with a solvent. By way of example, an n-heptane is a solvent.

According to an embodiment, provision is made for the adhesive, in particular the silicone, to be applied to the light-emitting surface by means of spraying (also referred to as spray coating) and/or by means of dispensing. The term “dispensen” [dispensing] can be referred to in German as “Molden” [molding] and denotes a process step in an injection molding method.

According to an embodiment, provision is made for the conversion layer to be sprayed onto the microlens structure. In particular, this brings about the technical advantage that the conversion layer can be applied onto the microlens structure in an efficient manner.

According to another embodiment, provision is made for the conversion layer to be formed as a conversion layer that maps a topography of the microlens structure. That is to say that, in particular, the conversion layer is applied onto the microlens structure in such a way that it maps the topography of the microlens structure. That is to say that, in particular, the conversion layer also has a topography which corresponds to the topography of the microlens structure. In particular, this brings about the technical advantage that it is possible to influence an emission characteristic of the optoelectronic lighting device. In particular, this, in an advantageous manner, allows a certain emission characteristic to be set. For the purposes of mapping the topography of the microlens structure, provision is made according to an embodiment for the conversion layer to have a thickness of between 1 μm and 100 μm.

According to another embodiment, provision is made for at least some of the microlenses to be formed as hemispherical lenses or as prisms. In particular, this brings about the technical advantage that a specific emission characteristic or optical imaging by means of the microlenses can be achieved. According to an embodiment, provision is made for all microlenses of the microlens structure to be formed as hemispherical lenses or as prisms.

According to one embodiment, provision is made for the microlens structure to comprise a glass and/or a plastic or to be formed from glass and/or from plastic. According to further embodiments, the microlens structure may comprise the following materials individually or in combination: fused silica, silicone, borosilicate glass, silicon dioxide (SiO₂).

According to an embodiment, the substrate is formed as a plate.

According to a further embodiment, the substrate is formed from fused silica, silicone or borosilicate glass, or comprises such a material or a plurality of such materials.

According to an embodiment, the substrate has a thickness of 100 μm. In particular, the substrate has a thickness of between 50 μm and 15o μm.

According to an embodiment, provision is made for arranging the microlens structure on the light-emitting surface to comprise arranging a substrate that comprises a plurality of microlenses on the light-emitting surface.

According to an embodiment, provision is made for the plurality of microlenses of the substrate to be formed integrally with the latter.

In another embodiment, provision is made for arranging the microlens structure on the light-emitting surface to comprise arranging microlenses that are formed in a singulated manner on the light-emitting surface such that the microlenses that are formed in a singulated manner are arranged separately from one another on the light-emitting surface.

In another embodiment, provision is made for the microlenses that are formed in a singulated manner to be each formed as a sphere. According to an embodiment, the spheres have a diameter of 50 μm. In particular, the spheres have a diameter of 20 μm to 100 μm. By way of example, the sphere is formed from silicon dioxide (SiO₂). A diameter of the sphere depends, in particular, on a color locus of the electromagnetic radiation that is emitted by means of the LED and/or on an LED dimension.

In accordance with a further embodiment, provision is made for arranging the microlens structure on the light-emitting surface to comprise adhesive bonding of the microlens structure onto the light-emitting surface.

According to another embodiment, provision is made for an adhesive layer to be applied onto the light-emitting surface, wherein microlenses that are formed in a singulated manner are applied onto the adhesive layer after the application of the adhesive layer, wherein microlenses that are formed in a singulated manner and exceed a monolayer after the application are removed from the adhesive layer such that the remaining microlenses that are formed in a singulated manner form a monolayer of microlenses that are formed in a singulated manner.

That is to say that, in particular, this can bring about the technical advantage that only a monolayer made of microlenses is applied onto the light-emitting surface. By way of example the removal comprises shaking-off of the excessive microlenses. Excessive microlenses are microlenses which exceed the monolayer, i.e., which are surplus to requirement.

By way of example, the application of the microlenses that are formed in a singulated manner comprises an immersion of the adhesive layer into a multiplicity of microlenses that are formed in a singulated manner.

In another embodiment, provision is made for the conversion layer to be sprayed onto the microlens structure.

In accordance with a further embodiment, provision is made for the conversion layer to be formed as a conversion layer that maps a topography of the microlens structure.

According to another embodiment, provision is made for at least some of the microlenses to be formed as hemispherical lenses or as prisms.

According to an embodiment, provision is made for the optoelectronic lighting device to be produced by means of the method for producing an optoelectronic lighting device.

In a further embodiment, the following lens profiles or lens forms may be provided for the microlenses: plano-convex, biconvex, aspherical or spherical.

According to an embodiment, the carrier is formed as a substrate.

In one embodiment, the light-emitting diode is formed as an LED chip.

In a further embodiment, the light-emitting diode is a laser diode.

In one embodiment, the microlens structure is arranged on the light-emitting surface in such a way that the microlenses are formed or arranged distant from the light-limiting surface.

According to one embodiment, the conversion layer comprises a phosphor.

In one embodiment, the conversion layer comprises silicone in order advantageously to adhesively bond the conversion layer to the microlens structure.

According to one embodiment, the carrier is a lead frame.

Device features emerge analogously from corresponding method features, and vice versa. That is to say that, in particular, technical functionalities, advantages and explanations, as made in conjunction with the optoelectronic lighting device, apply analogously to the method, and vice versa.

### BRIEF DESCRIPTION OF THE DRAWINGS

The above-described properties, features and advantages of this invention, and the manner in which they are achieved, will become clearer and more easily understandable in conjunction with the following description of the exemplary embodiments, which are explained in more detail in conjunction with the drawings, wherein

FIG. 1 shows a lateral sectional view of a microlens structure,

FIG. 2 shows an oblique top view of the microlens structure from FIG. 1,

FIG. 3 shows the microlens structure in accordance with FIG. 1 after singulation,

FIG. 4 shows an optoelectronic lighting device that is still without a conversion layer,

FIG. 5 shows the optoelectronic lighting device in accordance with FIG. 4, comprising a conversion layer,

FIG. 6 shows a further optoelectronic lighting device that is still without a microlens structure and a conversion layer,

FIG. 7 shows the optoelectronic lighting device in accordance with FIG. 6, comprising an adhesive layer,

FIG. 8 shows the optoelectronic lighting device in accordance with FIG. 7, comprising a microlens structure,

FIG. 9 shows the optoelectronic lighting device in accordance with FIG. 8, comprising a conversion layer, and

FIG. 10 shows a flowchart of a method for producing an optoelectronic lighting device.

Below, the same reference sign may be used for the same feature.

### DETAILED DESCRIPTION OF ILLUSTRATIVE EMBODIMENTS

FIG. 1 shows a microlens structure lot in a lateral sectional view.

The microlens structure 101 comprises a substrate 103. By way of example, the substrate 103 is formed as a glass plate. According to further embodiments, the substrate 103 may comprise the following materials, either individually or in combination: fused silica, silicone, borosilicate glass.

A plurality of microlenses 105, which are formed as hemispherical lenses, are arranged on the substrate 103. In accordance with the exemplary embodiment shown in FIG. 1, the microlenses 105 are formed integrally with the substrate 103. That is to say that, in particular, a microlens structure is impressed onto the substrate 103.

According to an embodiment, a thickness of the substrate 113 may be 100 μm.

In the embodiment shown in FIG. 1, the microlenses 105 are formed as hemispherical lenses. In further embodiments not shown here, the following lens profiles or lens forms may be provided: plano-convex, biconvex or aspherical or spherical. In an embodiment not shown here, provision is made for the microlenses 105 to be formed as prisms.

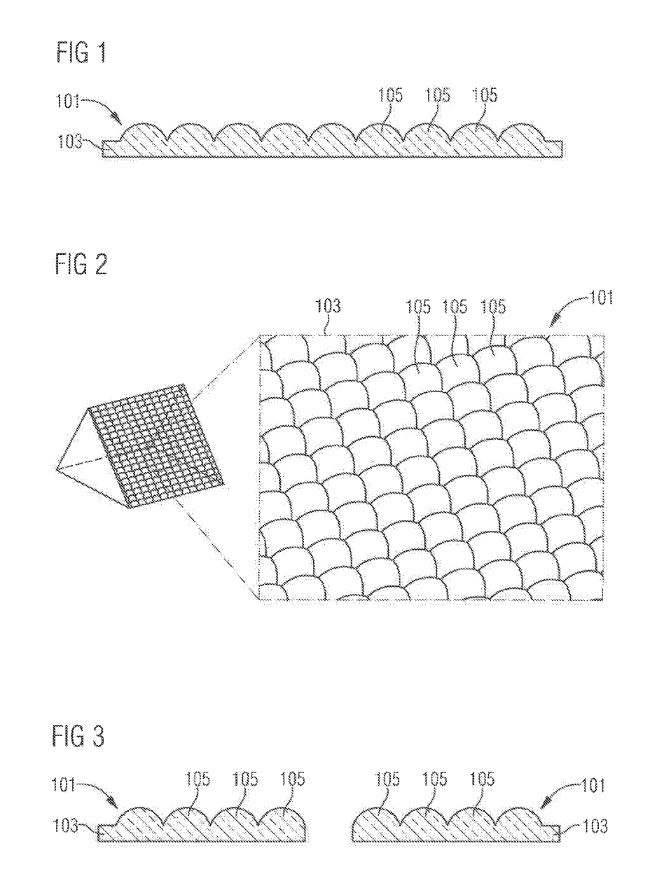

FIG. 2 shows the microlens structure lot in accordance with FIG. 1 in an oblique top view.

FIG. 3 shows the microlens structure lot in accordance with FIG. 1 after singulation.

That is to say that the microlens structure lot from FIG. 1 was singulated. By way of example, provision is made for the substrate 103 to have been divided. That is to say that, in particular, a plurality of partial substrates 103 was separated from the substrate 103. By way of example, the singulation of the substrate 103 may comprise sawing and/or laser separation and/or scribing with subsequent breaking. In FIG. 3, singulated substrates are denoted by reference sign 103 again for reasons of clarity. Accordingly, the microlens structures singulated thus are likewise provided with reference sign 101.

A size of the singulated microlens structures 101 is selected such that these are able to cover a light-emitting surface of a light-emitting diode. That is to say that, in particular, a size that corresponds to the light-emitting surface is selected for the singulated microlens structures 101.

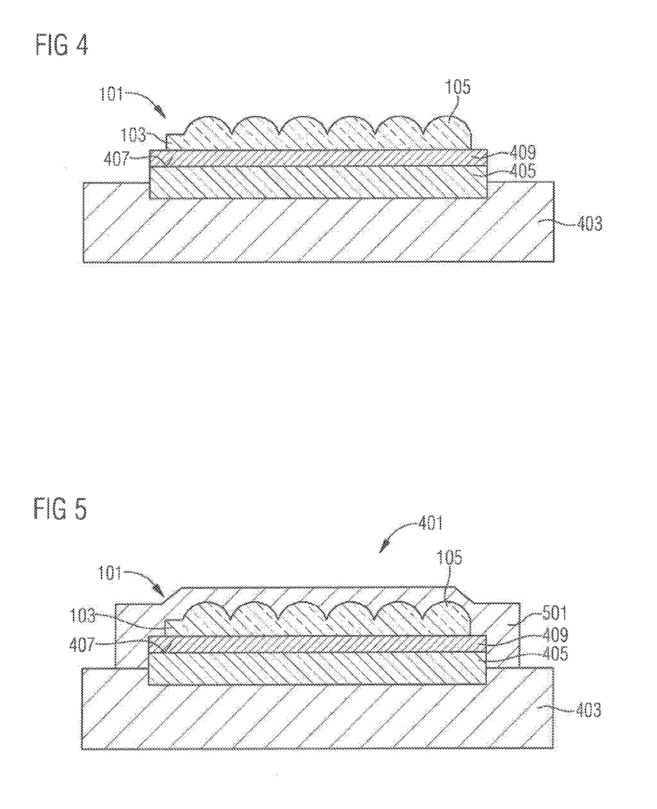

FIG. 4 shows an optoelectronic lighting device 401 that is still without a conversion layer.

The optoelectronic lighting device 401 comprises a carrier 403, which, for example, may be formed as a substrate. A light-emitting diode 405 is arranged on the carrier 403. By way of example, the light-emitting diode 405 is formed as an LED chip.

By way of example, the light-emitting diode 405 can be formed as a laser diode. In the embodiment shown in FIG. 4, the light-emitting diode 405 is partly embedded into the carrier 403. In an embodiment that is not shown here, provision can be made for the light-emitting diode 405 not to be embedded.

The light-emitting diode 405 comprises a light-emitting surface 407 that is distant from the carrier 403. An adhesive layer 409, which may, e.g., comprise silicone, is applied to the surface 407. That is to say that, in particular, e.g., a silicone layer is applied onto the light-emitting surface 407 as an adhesive layer 409.

The singulated microlens structure 101 in accordance with FIG. 3 is applied to the adhesive layer 409 such that the microlens structure lot is adhesively bonded onto the light-emitting surface 407. By way of example, the application of the microlens structure 101 onto the light-emitting surface 407 may comprise a die-bonding process, i.e., a placement of the microlens structure 101 onto the adhesive layer 409 by machine.

In the process, the microlens structure lot is arranged on the light-emitting surface 407 in such a way that the microlenses 105 are formed or arranged distant from the light-emitting surface 407.

Light that is emitted by means of the light-emitting surface 407 will therefore radiate through the microlens structure 105 and experience optical imaging by the latter.

FIG. 5 shows the optoelectronic lighting device 401 in accordance with FIG. 4, comprising a conversion layer 501.

By way of example, the conversion layer 501 comprises a phosphor. In particular, the conversion layer 501 comprises silicone in order advantageously to adhesively bond the conversion layer to the microlens structure lot and to the carrier 103 in an efficient manner.

After the application of the conversion layer 501, the conversion layer 501 covers at least the microlenses 105 of the microlens structure lot. This advantageously causes the light that is imaged by means of the microlens structure 101 to radiate through the conversion layer 501 and be converted therein at least in part, in particular in the entirety thereof.

By way of example, the conversion layer 501 is applied by means of a spraying process, so-called “spray coating”.

The optoelectronic lighting device 401 therefore comprises a pre-structured microlens structure lot. These are pre-structured as an already complete microlens structure is placed or arranged on the light-emitting surface 407. Here, in particular, pre-structured also means pre-manufactured.

Such pre-manufactured microlens structures are advantageously suitable, in particular, for light-emitting diodes which are configured as bar chips or as flip chips. In particular, such microlens structures, as are used for the optoelectronic lighting device 401, are suitable for light-emitting diodes without a bond notch, i.e., for light-emitting diodes which are formed as surface emitters with two rear side contacts. The term bond notch refers to a wire contacting surface on a chip surface.

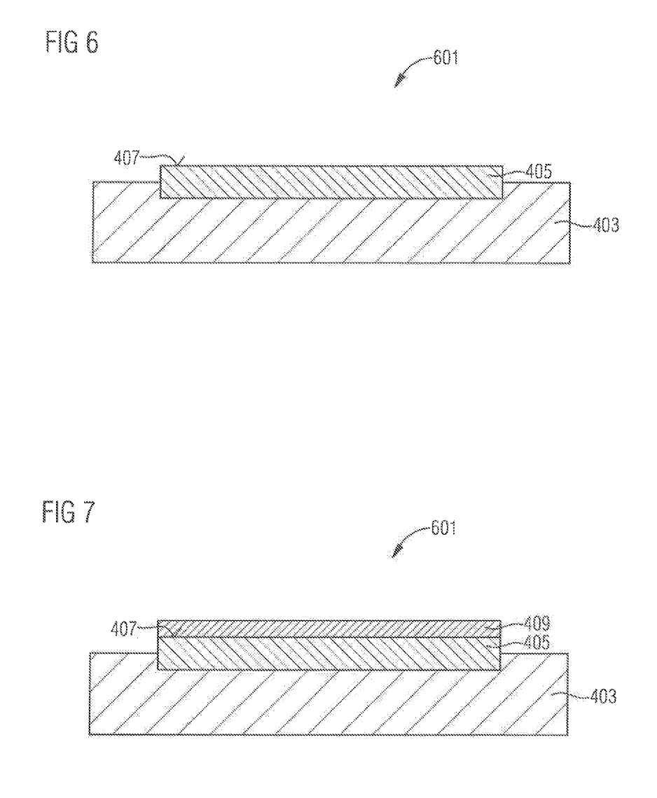

FIG. 6 shows a further optoelectronic lighting device 601 that is still without an adhesive layer, still without a microlens structure, and still without a conversion layer.

The optoelectronic lighting device 601, in a manner analogous to the optoelectronic lighting device 401, likewise comprises a carrier 403 and a light-emitting diode 405, which comprises a light-emitting surface 407.

FIG. 7 shows the optoelectronic lighting device 601, with an adhesive layer 409 having been applied onto the light-emitting surface 407. This adhesive layer 409 can be the same adhesive layer 409 as in the optoelectronic lighting device 401.

By way of example, a thin layer of a clear silicone can be applied to the light-emitting surface 407 of the light-emitting diode 405. This thin layer is the adhesive layer 409. Within the meaning of embodiments of the present invention, thin means that, in particular, the layer, for example, the adhesive layer 409 has a thickness of between 0.5 μm and 10 μm.

The adhesive layer 409 can be undiluted or diluted by a solvent, e.g., n-heptane. In particular, the adhesive layer 409 can be applied by means of a spraying process and/or a dispensing process.

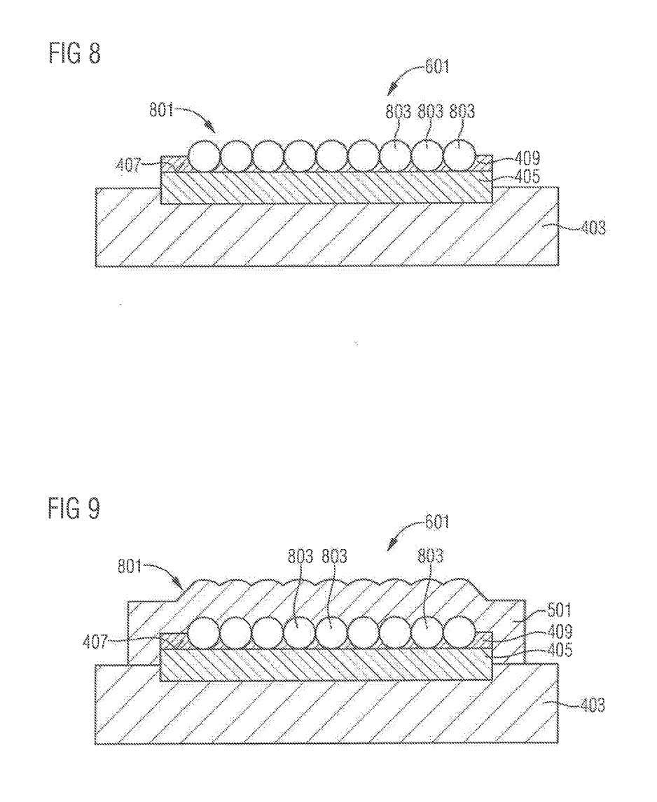

FIG. 8 shows the optoelectronic lighting device 601 in accordance with FIG. 7, comprising a microlens structure 801 that comprises a plurality of singulated glass spheres 803 as microlenses. By way of example these glass spheres 803 are formed from SiO₂, i.e., silicon dioxide, and have, e.g., a diameter of 50 μm. In accordance with one embodiment, these glass spheres 803, which can also be referred to as glass beads, are applied on the light-emitting surface 407 as outlined below.

By way of example, the optoelectronic lighting device 601 from FIG. 7 is immersed into a number of glass beads 803, at least the optoelectronic lighting device in accordance with FIG. 7 is immersed so far into a multiplicity of glass beads 803 that the adhesive layer 409 is immersed into this multiplicity of glass beads 803. This advantageously causes the glass beads 803 to adhesively bond or adhere to the adhesive layer 409.

According to an embodiment, a monolayer made of glass beads 803 is provided, said monolayer being arranged on the light-emitting surface 407. In order to remove glass beads 803 that are surplus to requirement from the adhesive layer 409 after the immersion, provision is made according to an embodiment for the glass beads 803 that are surplus to requirement to be shaken off.

After shaking off, provision is made, in particular, for the adhesive layer 409 to cure. This is carried out under predetermined conditions, i.e., at a predetermined temperature, for a predetermined period of time, and, for example, under irradiation by UV light.

FIG. 9 shows the optoelectronic lighting device 601 from FIG. 8 after a curing of the adhesive layer 409, with now, additionally, a conversion layer 501 having been applied onto the microlens structure 801 that comprises the glass beads 803.

According to one embodiment, the conversion layer 501 can be applied in a manner analogous to the conversion layer 501 of the optoelectronic lighting device 401.

According to one embodiment, provision is made for the conversion layer 501 to be applied onto the microlens structure 801 in such a way that, in the process, the topography of the glass beads 803 is largely mapped. So that a topography of the glass beads 803 can be mapped, provision is made according to an embodiment for a layer thickness of the conversion layer 801 above the glass beads 803 to be between 5 μm and 100 μm.

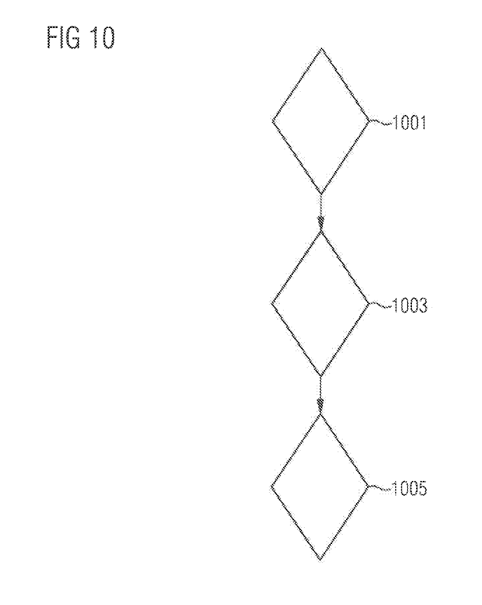

FIG. 10 shows a flowchart of a method for producing an optoelectronic lighting device.

The method comprises the following steps: providing tool a carrier, on which a light-emitting diode is arranged, arranging 1003 a microlens structure that comprises a plurality of microlenses on a light-emitting surface of the light-emitting diode, arranging 1005 a conversion layer on the microlens structure such that the light emitted by the light-emitting surface can be imaged, at least in part, by the microlens structure and then converted.

Thus, embodiments of the invention comprise, in particular and inter alia, the concept of producing a microlens structure on a light-emitting surface of a light-emitting diode, or to apply said microlens structure thereon. The microlens structure comprises, e.g., hemispherical lenses or prisms. Subsequently, provision is made according to an embodiment for the optically defined surface topography that is produced by the microlens structure to be coated with a conversion material, i.e., a conversion material is applied onto this surface topography. By way of example, this is carried out by means of the spraying process, i.e., by means of a “spray coating” process.

By the provision of the microlens structure in front of the conversion layer in relation to the emission direction of the primary light, it is advantageously possible to achieve improved mixing of different conversion paths and hence, ultimately, an improved color-over-angle behavior. As a result thereof, furthermore, an improvement in the color homogeneity is advantageously brought about. In particular, this advantageously brings about an influence on an emission characteristic.

Although the invention was more closely illustrated and described in detail by the preferred exemplary embodiment, the invention is not restricted by the disclosed examples and other variations can be derived therefrom by a person skilled in the art, without departing from the scope of protection of the invention.

1-19. (canceled)

20. An optoelectronic lighting device comprising:
a carrier;
a light-emitting diode arranged on the carrier having a light-emitting surface;
a microlens structure comprising a plurality of microlenses, wherein the microlens structure is arranged on the light-emitting surface of the diode; and
a conversion layer arranged on the microlens structure,
wherein the light-emitting surface is configured to emit light, wherein the microlens structure images, at least in part, the light, and wherein the conversion layer converts the light.

21. The optoelectronic lighting device according to claim 20, wherein the microlens structure comprises a substrate that comprises the plurality of microlenses, the substrate being arranged on the light-emitting surface.

22. The optoelectronic lighting device according to claim 21, wherein the plurality of microlenses are formed integrally with the substrate.

23. The optoelectronic lighting device according to claim 20, wherein at least some of the plurality of microlenses of the microlens structure are singulated microlenses, and wherein the singulated microlenses are arranged separately from one another on the light-emitting surface.

24. The optoelectronic lighting device according to claim 23, wherein each singulated microlens forms a sphere.

25. The optoelectronic lighting device according to claim 20, wherein the microlens structure is adhesively bonded to the light-emitting surface.

26. The optoelectronic lighting device according to claim 20, wherein the conversion layer is sprayed on the microlens structure.

27. The optoelectronic lighting device according to claim 20, wherein the conversion layer maps a topography of the microlens structure.

28. The optoelectronic lighting device according to claim 20, wherein at least some of the microlenses are hemispherical lenses or prisms.

29. A method for producing an optoelectronic lighting device, the method comprising:
arranging a light-emitting diode on a carrier, the light-emitting diode having a light-emitting surface;
arranging a microlens structure comprising a plurality of microlenses on the light-emitting surface of the light-emitting diode; and
forming a conversion layer on the microlens structure such that light emitted by the light-emitting surface is imaged, at least in part, by the microlens structure and then converted.

30. The method according to claim 29, wherein arranging the microlens structure on the light-emitting surface comprises arranging a substrate including the plurality of microlenses on the light-emitting surface.

31. The method according to claim 30, wherein the plurality of microlenses are formed integrally with the substrate.

32. The method according to claim 29, wherein arranging the microlens structure on the light-emitting surface comprises arranging singulated microlenses on the light-emitting surface such that the singulated microlenses are arranged separately from one another on the light-emitting surface.

33. The method according to claim 32, wherein each singulated microlens comprises a sphere.

34. The method according to claim 29, wherein arranging the microlens structure on the light-emitting surface comprises adhesively bonding the microlens structure on the light-emitting surface.

35. The method according to claim 29, further comprising:
forming an adhesive layer on the light-emitting surface;
applying the singulated microlenses on the adhesive layer; and
removing excessive singulated microlenses so that the remaining microlenses form a monolayer.

36. The method according to claim 29, wherein forming the conversion layer comprising spraying the conversion layer on the microlens structure.

37. The method according to claim 29, wherein the conversion layer maps a topography of the microlens structure.

38. The method according to claim 29, wherein at least some of the microlenses are hemispherical lenses or prisms.
